(19) United States
(12) Patent Application Publication
(10) Pub. No.: US 2007/0134560 A1
(43) Pub. Date: Jun. 14, 2007

(54) Lithography system using a programmable electro-wetting mask

(75) Inventors: Peter Dirksen, Leuven (BE); Robert Andrew Hayes, Eindhoven (NL); Casparus Anthonius Henricus Juffermans, Leuven (BE); Thomas Steffen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/596,598

(22) PCT Filed: Dec. 1, 2004
(86) PCT No.: PCT/IB04/52620

§ 371 Date: Jun. 19, 2006

(30) Foreign Application Priority Data
Dec. 22, 2003 (EP) 03104914.1

(51) Int. Cl. G03F 1/00

(52) U.S. Cl. 430/5

(57) ABSTRACT

A maskless lithography system is described having a programmable mask to allow performing several lithographic steps using the same mask. In every lithographic step, the corresponding pattern is obtained by providing a digital pattern to the programmable mask. The programmable mask includes an array of pixels which are based on the electro-wetting principle. According to this principle, every pixel has a transparent reservoir containing a first, non-polar, non-transparent fluid and a second, polar, transparent fluid which are immiscible. Applying a field to the reservoir allows to displace the fluids with respect to each other. This allows to make the pixel either transparent or non-transparent. This lithographic programmable mask allows high resolution and fast setting and refreshing. A corresponding method for performing maskless optical lithography also is described.

The present invention relates to a method, materials, apparatus and a system to perform optical lithography. More particularly, the invention relates to an optical lithographic method and system allowing high throughput for lithographic patterning of substrates using a programmable mask.

Lithography is one of the key techniques in the production of todays integrated circuits (IC's). In conventional lithographic systems, one or more lithographic masks is used to allow patterning during the production of IC's used in todays electronic devices. These masks need to be of high quality in order to avoid incorporating defects during the production of IC's. Therefore, the production of a set of lithographic masks, which typically consists of 10 to 20 masks, implies a significant production effort and production time. This leads to both the production cost of the masks being a large part of the production costs of IC's, and the speed of the production of IC's being reduced. Especially in prototyping and small volume production, but also in any business development, which is nowadays challenging since predicted maskcost are only met if the planned number of redesigns are met, it would be advantageous to reduce mask costs and mask cycle time.

In an industry in which the first mask sets exceeded 1M USD for the 90 nm node and exceeded 3M USD in the 65 nm node, and with doubling or tripling maskprices per technology node it is furthermore a must to have both initial cost control at the design/prototype phase and a cost control in the lifecycle, i.e. redesigns and romcodes, of a product. Consequently, it would be advantageous if the use of conventional lithographic masks could be avoided. The latter principle is referred to as “maskless” lithography.

The principle of maskless lithography is not new. A first example is e-beam lithography. In this technique, an electron-beam is used to write a pattern, obtained from a ‘mask’ database, directly on an electron beam resist. This resist is then developed. This technology is widely distributed in Research & Development institutes, but two main limitations prevents it from usage in an industrial environment

a) the throughput is very low, i.e. up to just a few wafers per day, and

b) furthermore the infrastructure, i.e. both the tool for lithographic processing and the chemistry of photoresists, does not fit the infrastructure of conventional lithography. The relatively low throughput is fundamentally limited by the electron-electron interactions. Furthermore, the corresponding technology is also less reliable than optical technology, as it requires a vacuum, suffers from charging of the substrate and from high voltage effects. Other focused-beam direct-writing systems, such as raster scanning with a blue or ultra-violet laser, suffer from the same major problem, i.e. the systems are extremely slow because the patterning process occurs on a bit-by-bit serial mode.

Another example of maskless lithography is optical maskless lithography. This refers to a lithographic technique based on photons, whereby the conventional, i.e. fixed, reticles are replaced by a so-called pattern rasterizer to create a pattern bitmap. This technique, in contrast to direct-writing systems, allows the use of existing infrastructure in terms of tools, tool platform, chemistry.

An example of optical maskless lithography is the use of spatial light modulators (SLM) as pattern rasterizers instead of conventional reticles. U.S. Pat. No. 6,312,134 (Anvik Corporation) describes the use of deformable micromirror devices, also called digital mirror devices, (DMD) in a programmable mask for reflection lithography purposes. Furthermore, as an alternative, the use of liquid crystal light valves (LCLV) in a programmable mask is described for transmission lithography purposes. The use of DMD and LCLV allows optical maskless lithography at relative high speed, e.g. compared to e-beam lithography.

Nevertheless, the DMD technology requires relative large pixels in the programmable mask, i.e. the size of the mirrors is relatively large (˜10 μm²), leading to the need of a large reduction, i.e. for example 200 to 400 times, if a sufficient resolution is to be obtained. Another disadvantage is that the number of pixels is for practical reasons limited to, e.g. 10⁶. A further disadvantage is that there is an amount of “dead” space between the pixels, leading to a decrease in quality of the lithographic process. Furthermore, DMD-based programmable masks have only a limited refresh rate, i.e. the speed with which the mask can be changed is limited by the mechanical properties of the DMD. An additional disadvantage is the vast amount of data rate that is needed during programming and processing using a DMD-based programmable mask. The data rate is in the range of 100 Gbit per second, as after one illumination, free electrons are generated in the DMD and SLM devices which makes that after each single illumination the mirrors of the optical mask are oriented randomly. The LCLV technology has the disadvantage that it is not suitable for deep ultra violet (DUV) or vacuum ultra violet, that it uses polarisers which decreases the intensity obtainable on the substrate, and that the refresh rate for LCLV devices is low.

It is an object of the present invention to provide a method, materials, apparatus and a system for maskless optical lithography allowing high throughput lithographic processing.

It is also an object of the present invention to provide a method and apparatus for uniquely identifying a substrate or a number of ICs using lithographic processing.

The above objective is accomplished by a method and system according to the present invention.

In one aspect the present invention relates to a programmable lithographic mask for use in an optical lithographic setup using a lithographic illumination source. The programmable mask comprises a number of pixels. Each pixel comprises a first, non-polar fluid that is not transparent for the lithographic illumination source, i.e. whereby the illumination beam of the lithographic illumination source is absorbed strongly, and a second, polar fluid that is transparent for the lithographic illumination source, i.e. whereby the illumination beam of the lithographic illumination source is only weakly absorbed. The fluids are immiscible. The programmable lithographic mask also comprises means for driving pixels individually or in groups to thereby displace the first and the second fluid with respect to each other. Preferably, the driving is on a pixel-by-pixel basis, at least in a part of the mask. The programmable lithographic mask may furthermore comprise a reservoir having walls which are transparent for the radiation from the lithographic illumination source and containing the first, non-polar fluid and the second, polar fluid. One of the walls may be a lyophobic wall, repelling the second, polar fluid. The pixels of the programmable lithographic mask may comprise an electrode, for applying an electric field to the fluids by applying a voltage between the electrode and a liquid counter electrode which may be common to several or all pixels. The programmable mask is also called an electro-wetting mask as it is based on pixels operating according to the electro-wetting principle. The electrodes may be transparent for the radiation from the lithographic illumination source. The programmable lithographic mask may furthermore comprise a reflective coating, i.e. the electrode may be reflective or an additional reflective coating may be provided.

The means for driving every pixel or groups of pixels may be means for active matrix driving or means for passive matrix driving. In the programmable lithographic mask, the first, non-polar fluid may be an oil and the second, polar fluid may be an aqueous solution or may be water. Furthermore, means for providing a fixed, non-programmable pattern in a number of areas of the programmable lithographic mask may be provided. These means may be a conventional lithographic mask or a phase shift mask or an attenuated phase shift mask.

The invention also relates to a system for maskless optical lithography, the system comprising an illumination source, a programmable electro-wetting mask, e.g. as described above and controlling and driving means for setting the programmable electro-wetting mask according to a lithographic pattern and for driving the pixels of the electro-wetting mask in accordance with the pattern. The system furthermore may comprise a first optical means for focussing an illumination beam of the illumination source. This focussing may be performed based on the Köhler principle, wherein the illumination beam is focussed in a plane located in the first optical means. The system furthermore may also comprise a second optical means for guiding and focussing the illumination beam, modulated according to the lithographic pattern of the programmable electro-wetting mask. Furthermore, means for aligning the substrate relative to the programmable lithographic mask may be provided. A blocking means for blocking the illumination beam during alignment and during setting of the programmable mask may be provided. The illumination source of the system also may be a pulsed illumination source and alignment and setting may be performed in between illumination pulses. The first and/or the second optical means may be based on mirrors, beamsplitters and/or lenses. The pixels of the electro-wetting mask of the system may comprise means for reflecting the illumination beam that has passed the first and/or the second fluid.

The invention furthermore relates to a method for performing an optical lithographic step on a substrate. The method comprises the steps of providing a digital pattern to a controlling and driving means of an electro-wetting mask, using the digital pattern to modulate a light pattern by means of the electro-wetting mask and illuminating the substrate through the electro-wetting mask. The method furthermore may comprise the step of mounting the substrate on an substrate stage and aligning the substrate relative to the electro-wetting mask. The method may furthermore comprise coating the substrate with a photosensitive material before illumination of the substrate. During the illumination of the substrate, the electro-wetting mask and the substrate may be moved in the same direction or the electro-wetting mask and the substrate are moved in opposite direction, the direction depending on the sign of the magnification, i.e. the same direction if a direct image is formed and the opposite direction if an inverted image is formed. The speed of travelling of the masks may depend on the magnification of the optical system of the photolithographic setup. Illumination may be performed by scanning the electro-wetting mask with a narrow beam and at the same time shifting the substrate accordingly, to illuminate the substrate with the corresponding lithographic pattern.

In a further aspect the present invention may relate to a method for labelling a substrate in an optical lithographic step. The method comprises the steps of providing one or more unique identification indicia, such as one or more alphanumeric, numeric or alphabetical characters in a digital pattern in order to provide every substrate with a unique identification label, and providing the digital pattern to a controlling and driving means of an electro-wetting mask. The digital pattern is used to modulate a light pattern by means of the electro-wetting mask and illuminating the substrate through the electro-wetting mask. The method furthermore may comprise providing unique identification labels in the digital pattern in order to provide every die on a substrate with a unique identification label.

The method may include refreshing the unique identification numbers in the digital pattern during optical lithography of a plurality of substrates, so as to provide a unique identification number for every die of the plurality of substrates.

The present invention also includes a method of making a device comprising the steps of providing a photoresist layer on a layer which is to be patterned, illuminating the photoresist layer with a corresponding pattern obtained by modulating an illumination source with an electro-wetting mask, developing the photoresist layer and processing the substrate to obtain the patterned layer. This processing may be an etching process

It is an advantage of the current invention that the method and system for maskless optical lithography is fully transparent with present conventional and future optical lithographic infrastructure and currently applied chemistry so that it can be mixed and matched with existing lithographic wafer scanners and steppers.

It is a specific advantage of the current invention that the programmable mask has a high refresh rate.

It is a specific advantage of the current invention that the throughput is sufficiently high so that it becomes feasible to eliminate masks in terms of cost and cycle times and/or apply this technology in a dual source way.

It is an advantage of maskless lithography according to the current invention that it allows quick prototyping, it can reduce cost and it can be used for small series of wafers.

Although there has been constant improvement, change and evolution of systems and methods in this field, the present concepts are believed to represent substantial new and novel improvements, including departures from prior practices, resulting in the provision of more efficient, stable and reliable methods and systems of this nature.

The teachings of the present invention permit the design of improved methods and systems for optical maskless lithography. These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

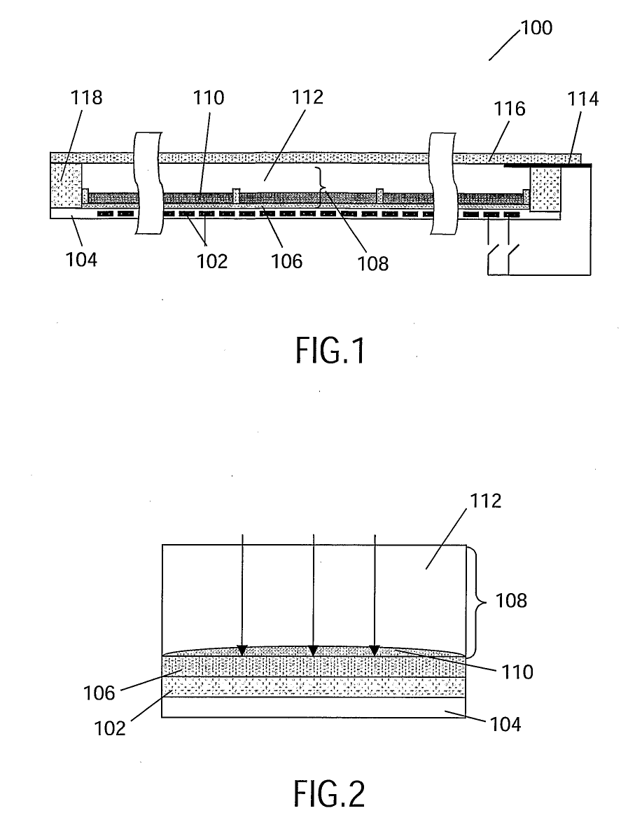

FIG. 1 is a schematic representation of a transmission optical lithographic electro-wetting mask according to an embodiment of the present invention.

FIG. 2 is an illustration of the electro-wetting principle showing a schematic representation of an electro-wetting pixel in an OFF state according to an embodiment of the present invention.

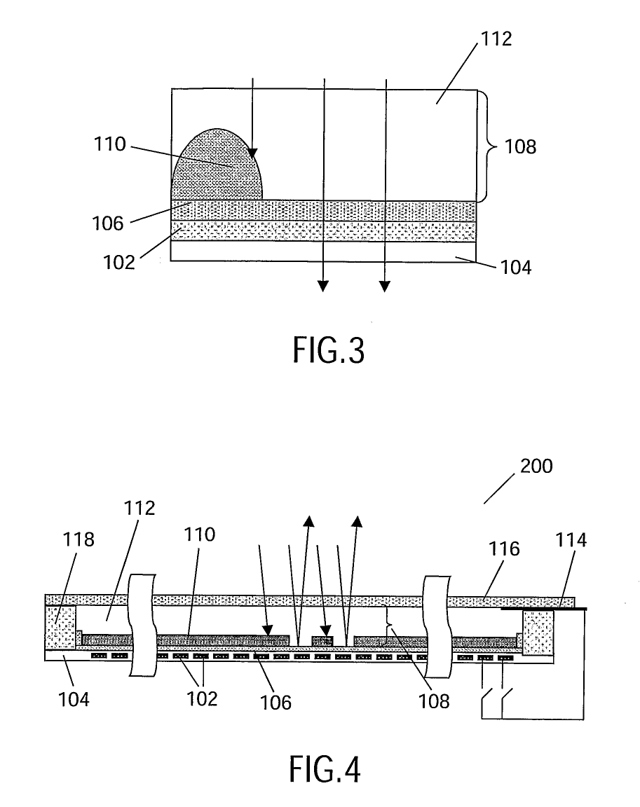

FIG. 3 is an illustration of the electro-wetting principle showing a schematic representation of an electro-wetting pixel in an ON state according to an embodiment of the present invention.

FIG. 4 is a schematic representation of a reflection optical lithographic electro-wetting mask according to an embodiment of the present invention.

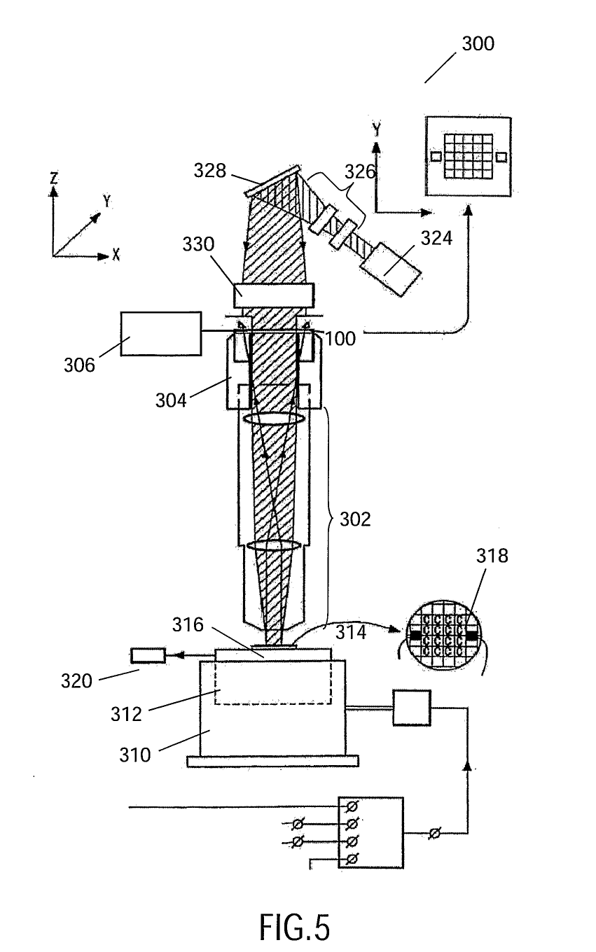

FIG. 5 is a schematic representation of an optical maskless lithographic system in a transmission configuration using a transmission electro-wetting mask according to an embodiment of the present invention

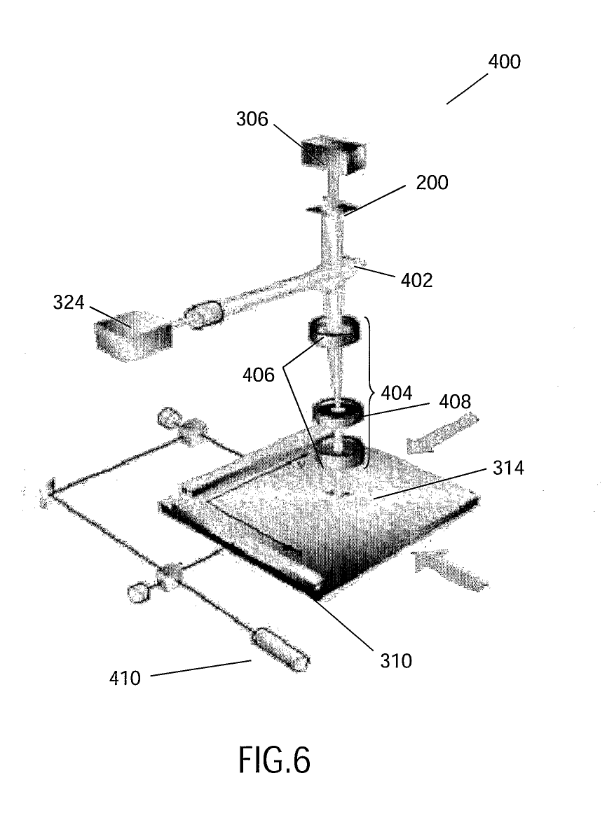

FIG. 6 is a schematic representation of an optical maskless lithographic system in a reflection configuration using a reflection electro-wetting mask according to an embodiment of the present invention.

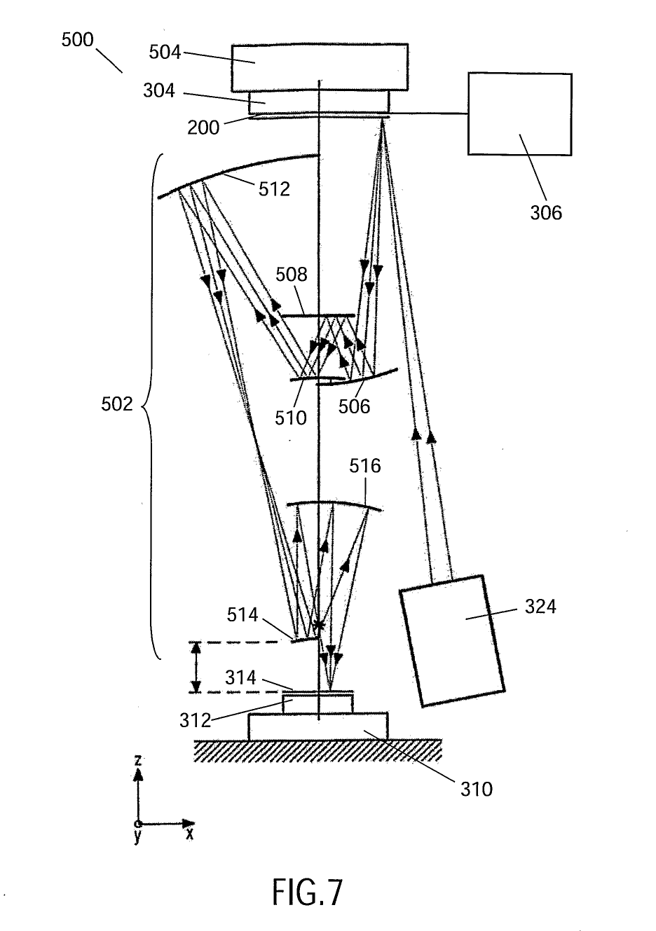

FIG. 7 is a schematic representation of another reflection configuration for an optical lithographic system using a reflection electro-wetting mask according to an embodiment of the present invention.

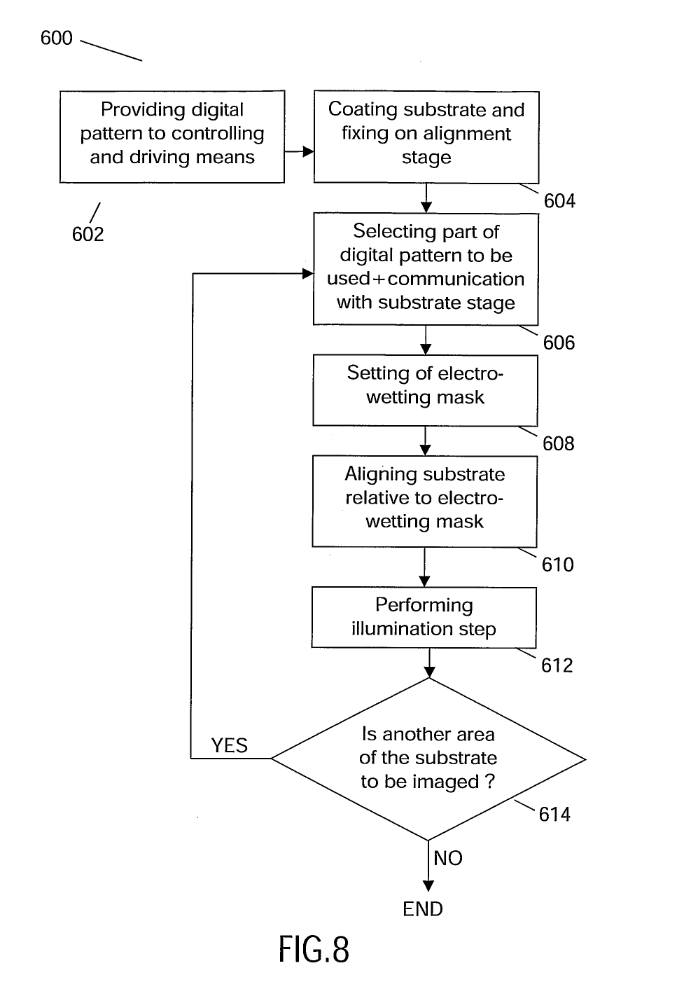

FIG. 8 is a block diagram showing a method for performing optical maskless lithography according to an embodiment the present invention.

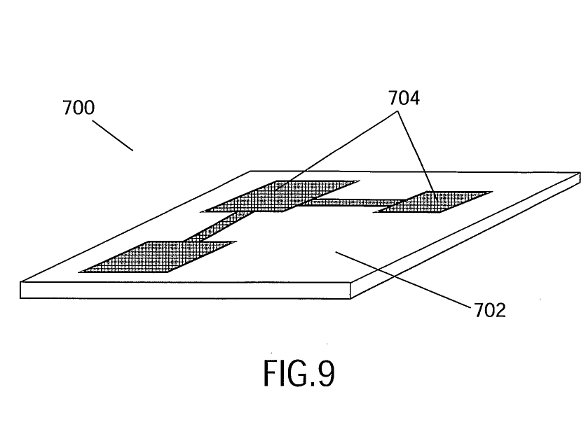

FIG. 9 is a schematic representation of a mask spatially combining both a programmable and a non programmable mask according to an embodiment of the present invention.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

The terms lyophilic (liquid-attractive) and lyophobic (liquid-repelling) describe the tendency of a surface to become wetted by a liquid. Hydrophilic and hydrophobic refers to the particular case when the liquid is aqueous and refers to an attractive or a repellent force for aqueous solutions or water. In the following description, e.g. oil and water will be used as the non-polar and polar liquids. Consequently, the terms hydrophobic and hydrophilic are used. However, it should be understood that any combination of liquids and surfaces which provides the necessary combination of polarity and non-polarity and lyophobic/lyophilic effect, respectively, can be used instead. In a first embodiment, the invention relates to an electro-wetting lithographic mask for use in a transmissive maskless optical lithographic system. The electro-wetting mask 100 comprises an array of electrodes 102, deposited on or embedded in a first transparent substrate 104, a hydrophobic insulator 106, a fluid channel 108 wherein a first fluid 110 and a second fluid 112 are provided, which are immiscible, and a liquid counter electrode 114 on a thin second transparent substrate 116.

The electrodes 102 typically are transparent conductors which have good transparency for the wavelength of the illumination source used in the lithographic system, e.g. for patterning a photosensitive layer. Typical materials that are used are e.g. indium tin oxide (ITO), tin oxide SnO₂, zinc oxide aluminum ZnOAl, or similar The characterising dimension of the electrode 102, i.e. for example the side of a square electrode, typically is smaller than 10 μm, i.e. preferably between 5 and 0.5 micrometer. The spacing between the electrodes typically is between 50 nm and 250 nm. The number of electrodes present influences the resolution of the electro-wetting mask. In other words, the number of electrodes determines the number of pixels in the electro-wetting mask that can be set or adapted. The illumination beam can either be absorbed or transmitted for every single pixel, according to how the pixel is driven in the electro-wetting mask.

The number of electrodes is only limited by the demagnification in the lithographic setup and by the size of the electro-wetting mask 100. Typically the number of optical elements ranges up to 10⁶ optical elements, preferably up to 10⁷ optical elements, more preferably up to 10⁸ optical elements and most preferably up to 10⁹ optical elements. The latter allows to process a complete die, i.e. the area taken by one chip, at the time. The total surface of the pixel array has a size of the order of magnitude of 1 cm² to 100 cm².

The transparent substrate 104 used may be made of any suitable transparent material of which glass, quartz and plastic are only two examples. The material used should be transparent for the wavelength of the light source used for lithography.

The hydrophobic insulator 106 may e.g. be a fluoropolymer insulator. This may be e.g. an amorphous fluoropolymer such as AF 1600. The thickness of this hydrophobic insulator 106 typically ranges between 1 μm and 0.1 μm. A thinner layer thickness allows a lower driving voltage, which is preferential if high switching speeds are to be obtained.

In the fluid channel 108, two immiscible fluids are provided. A first fluid 110 can e.g. be an alkane like hexadecane or an oil, e.g. a silicone oil. The optimum thickness of the film depends on the pixel size. Typically, the thickness relates to the characteristic length of the pixel with an aspect ratio between 1/10 and 1/20. A smaller layer thickness allows a more sharp definition of the pixel area. The second fluid 112 is an electrolyte or electroconductive or polar fluid, e.g. water or a salt solution, like e.g. a solution of a salt in water, e.g. KCl. The thickness of the electrolyte layer is not expected to be very critical for operating the pixels in the electro-wetting mask. This typically is about 100 micron, which allows a sufficient conduction in this layer. Other liquids or combinations can be used; an important characteristic is that they are immiscible. For example, one of them can be polar, e.g. water or aqueous based, while the other one is non-polar, e.g. a hydrophobic liquid such as an oil.

According to the present invention, the liquids typically are chosen to have different levels of transmission, e.g. of transparency. Typically, the first fluid 110 has a low degree of transparency for the wavelength of the illumination source used in the lithographic setup and the illumination light is absorbed for more than 50%, preferably more than 75%, more preferably more than 90% in the first fluid 110 and thus is at least blocked if the first fluid 110 is in the light path. The optical density of the first fluid 110 typically is larger than 0.5, preferably larger than 2. If, on the other hand, the first fluid 110 is displaced, some of the illumination light passes only through the second fluid 112, i.e. not through the first fluid 110. The second fluid 112 typically has a high degree of transparency for the wavelength of the illumination light in the lithographic setup. The optical density typically is smaller than 0.1, preferably smaller than 0.05. The ratio of the optical density of the first liquid to the optical density of the second liquid typically ranges between 5 and 40 and preferably is as high as possible. The illumination light thus passes through the electro-wetting mask. Thus, by displacement of the fluids, the electro-wetting mask 100 may function as a controllable light filter or light modulating device for the illumination source in the lithographic process.

As during blocking of the illumination beam, the electro-wetting mask can not guarantee 100% absorption of the illumination beam, illuminated parts are better defined than non-illuminated parts. Therefore, it is preferential to use a negative resist if lithography with an electro-wetting mask is used, as this allows to preserve the illuminated parts of the photoresist during development.

The top electrode 114 also is a transparent top electrode, such as e.g. indium tin oxide (ITO), tin oxide SnO₂, zinc oxide aluminium ZnOAl, or similar. It typically is applied or deposited on a thin transparent substrate 116 and it is in contact with at least the second fluid 112. The fluid channel 108 also is sealed at the edges of the electro-wetting mask with sealing blocks 118.

Small barriers can be provided in the electro-wetting mask for allowing better control of the first fluid layer thickness. These barriers typically can be provided at regular distances in the electro-wetting mask 100, e.g. every 100 pixels, for both lateral directions of the electro-wetting mask.

Additionally, the electro-wetting mask 100 also can be provided with an antireflective coating on its bottom side in order to prevent light that is specularly reflected from the substrate surface, which typically is a coated wafer surface, being redirected onto the wafer surface again due to reflection.

The electro-wetting lithographic mask is based on the electro-wetting effect, which is a known phenomenon, e.g. described in the article by R. Hayes and B. Feenstra in Nature, vol. 425 (2003) p 383. The effect is illustrated in FIG. 2 and FIG. 3 showing two different states for a pixel based on the electro-wetting effect. The electro-wetting effect essentially is a phenomenon whereby an electric field modifies the wetting behaviour of a second fluid 112, which is a polar liquid, in contact with a hydrophobic surface. By applying an electrostatic field, a surface energy gradient is created in the second fluid 112, which can be used to manipulate the fluid. The manipulation is determined by the magnitude of the electrostatic field.

FIG. 2 shows a pixel wherein no electric field is applied. The fluid channel 108 is chosen such as to have one hydrophobic wall and one non-hydrophobic wall, the hydrophobic surface will by nature reject the polar surface and, by configuring the surfaces properly, the spatial relationship between the liquids can be predetermined, i.e. the second fluid 112 is forced to a predetermined location opposite the hydrophobic surface. By applying a voltage, the interaction between the hydrophobic wall and the second fluid 112 can be compensated and the second fluid 112 can be attracted to the hydrophobic surface, thereby displacing the first fluid and forming a small droplet of this material. This is shown in FIG. 3. Using first and second fluids having different transparency levels for the wavelength of a radiation source allows to set the status of the pixel such that it either allows light to be guided further or to block light. In FIG. 2 and FIG. 3 the principle is illustrated for transmitting pixels, but the principle can also be used for reflecting pixels, by providing a reflecting surface at the bottom of the pixels.

The size of the area of the pixel that is made transparent depends on the shape of the droplet of first fluid 110 that is formed and the voltage that is applied. It is to be noted that, upon break-up of the first fluid 110 layer into droplets, the area fraction of the pixel covered with the first fluid 110 is reduced practically instantly to about 50%. At practical voltages, i.e. in view of driving the electro-wetting mask 100 using IC drivers, a minimal area fraction of about 25% of the pixel area is always covered with first fluid 110 droplets. This can be decreased further if higher voltages are applied, but this would increase the dissipated power significantly and possibly preclude the use of low voltage IC drivers. The OFF state corresponds with the state wherein the absorbing fluid covers the complete pixel area and thus no transmission or reflection of light is allowed. The voltage that needs to be applied to turn the pixel in an ON-state depends on the layer thicknesses of the fluids and the exact materials used. The voltage typically ranges between 2V and 20V.

The area where the formation of droplets will initiate and the area of the pixel to which the droplet will be driven, is determined by inhomogeneities of the pixel. In order to obtain more uniformity between different pixels, the electrodes may be shaped more specifically or additional electrodes may be provided so that the droplet of first fluid 110 is moved to the same edge for all pixels.

In a second embodiment, the invention relates to an electro-wetting mask for use in a reflection maskless optical lithographic setup. A schematic representation of a reflection electro-wetting mask 200 is given in FIG. 4. The reflection electro-wetting mask 200 has the same features as the transmission electro-wetting mask 100, except for the bottom electrode and the bottom substrate. Instead of having a transparent bottom electrode and bottom substrate, at least the pixel electrodes 102 and possibly also the substrate 104 is reflective. The bottom electrodes 102 can be made of a suitable reflective material or have such a coating, examples are aluminium or chromium, although any other highly reflective and non-transparent conducting material can be used. The thickness for Al or Cr electrodes typically is between 20 nm and 50 nm, as to obtain an optical non-transparent layer. The substrate 104 used is a non-conducting specular reflecting substrate. In operation, light from e.g. an illumination source is either absorbed by the first fluid 110, if the latter is in the light path, or it passes through the second fluid 112, reflects at the electrodes 102 and possibly also on the specular reflecting surface and passes the second fluid 112 again to be guided further on e.g. a substrate surface. The attenuation of the illumination beam intensity by the reflection electro-wetting mask is twice as large as the attenuation by the transmission electro-wetting mask, as the illumination beam passes twice through the second fluid 112, before it can be guided further to the substrate.

The transmission and reflection electro-wetting lithographic masks can be used in several different optical maskless lithographic setups. These masks thus act as a programmable mask which allows to switch the digital mask pattern by resetting the pixels of these masks and thereby eliminates the need to replace the mask if another pattern is to be applied during lithography, either in different lithographic steps during a number of subsequent lithographic pattern steps to produce a complete integrated circuit or if different patterns need to be used during wafer stepping in a single lithographic patterning step. The transmission electro-wetting lithographic mask 100 can be used in transmission in a conventional transmission optical lithography configuration, in a contact printing mode or in a +1× magnification printing mode. Furthermore, the reflection electro-wetting mask 200 may be used in a reflection optical lithography configuration using a beam splitter, or in a reflection optical lithography configuration using mirrors.

In a third embodiment of the invention, a transmission optical maskless lithographic system 300 is described, using the transmission electro-wetting lithographic mask 100 described in the first embodiment. FIG. 5 shows a schematic representation of a transmission maskless optical lithography setup 300 including a transmission electro-wetting mask 100, a projection column accommodating a projection lens system 302, a mask holder 304 for accommodating the electro-wetting mask 100, driving and controlling means 306 for the electro-wetting mask 100 and a substrate table 310 supporting a substrate holder 312 for accommodating a substrate 314. This may be any suitable substrate, for example a semiconductor substrate, also referred to as a wafer. Typical substrates used in the production of IC's are wafers of silicon Si, germanium Ge, silicon-germanium SiGe, indium phosphide InP, gallium arsenide GaAs. This substrate is provided with a radiation sensitive layer, for example a photoresist layer 316, on which the lithographic pattern must be imaged, e.g. by performing lithography on a number of adjacent areas on the substrate. In some cases the same pattern needs to be applied to adjacent areas, i.e. if every lithographic illumination corresponds with lithographic processing of one integrated circuit. The area covered in a lithographic step then is typically called a die 318. In the latter case, the same mask can be used for the lithographic processing of the whole substrate. If the adjacent areas doe not have the same pattern, e.g. if the pattern can only cover part of an integrated circuit, the pattern of the electro-wetting mask will need to be refreshed several times to allow patterning of the whole substrate area. The photoresist layer 316 used typically is a chemical amplified resist. The substrate table is movable in the X and Y directions so that after imaging the mask pattern in one area, a subsequent area can be positioned under the electro-wetting mask 100 pattern. For an accurate determination of the X and Y positions of the substrate 314, a lithographic apparatus may be provided with a high-precision positioning system such as e.g. a multi-axis interferometer system 320. Examples of such systems are described in e.g. U.S. Pat. No. 4,251,160, U.S. Pat. No. 4,737,823 and EP-A 0 498 499.

The controlling and driving means 306 for controlling and driving the electro-wetting mask 100 is adapted to receive a digital pattern for the electro-wetting mask 100, i.e. a digital pattern describing how the pixels of the electro-wetting mask 100 should be set. This digital pattern may correspond to the whole substrate, i.e. the digital pattern that will be used for patterning of the whole substrate. In this case, during processing a partial area of the substrate digital pattern may be selected. The controlling and driving means 306 may be equipped with a computer device for inputting such a pattern using a conventional drawing or imaging program, or/and the controlling and driving means 306 may be equipped with an input means for inputting the pattern from an external source. This external source may be e.g. a disk drive, a CD-ROM reader, a DVD reader, a network.

The controlling and driving means 306 for the electro-wetting mask further may be adjusted to drive the electro-wetting mask either as passive matrix or as active matrix. If the electro-wetting mask is active matrix driven, a matrix of switching elements e.g. thin film transistors (TFT) may be chosen for applying the driving signals. The thin film transistors are present on the mask, preferably at locations where no electrodes 102 are present. If necessary this area and possibly also other inter-pixel areas may be covered by a black matrix to enhance contrast. The advantage of active matrix addressing is that the refresh rate for the electro-wetting mask is higher than for passive matrix addressing. In order to allow passive matrix addressing, additional electrodes may be provided for the electro-wetting pixels to allow a bistable status of the pixels. A more detailed description, albeit for an electro-wetting display, is provided in patent application EP03100460.9 entitled ‘A passive matrix display with bistable electro-wetting cells’.

The apparatus further includes an illumination system which is provided with an illumination source 324, a lens system 326, a reflector 328 and a condenser lens 330. Different types of illumination sources 324 can be used for maskless optical lithography. Well known illumination sources 324 for lithography are the g-line, i.e. emission at 436 nm, and the i-line, i.e. emission at 365 nm, of mercury-arc lamps leading to a typical energy of 100 to 200 mJ/cm² on the substrate 314. These illumination sources 324 operate by collecting the light using an elliptical mirror and removing the undesired wavelenghts e.g. by using multilayer dielectric filters. Other typical illumination sources 324 for performing optical lithography are the deep UV lines at 248 μm, 193 nm and 157 nm of a krypton-fluoride excimer laser, having a typical energy delivered at the wafer surface of 20 mJ/cm². KrF excimer lasers are commercially available from e.g. Cymer Inc., Lambda Physik or Komatsu. Although these illumination sources 324 are the most conventional ones used in lithography, applying an electro-wetting mask 100 in the optical lithographic setup is not limiting the use of other less conventional illumination sources 324 for lithography. Examples of other illumination sources 324 that can be used are a frequency-quadrupled neodymium yttrium-aluminum-garnet (YAG) laser or a frequency-doubled copper vapour laser. In operation, the projection beam supplied by the illumination system illuminates the pattern of the electro-wetting mask. This typically is performed using Köhler illumination. The illumination source thereby is focussed on a plane, typically called the pupil, which is situated in the condenser lens 330. Köhler illumination allows to obtain a large degree of homogeneity for the intensity of the illumination source 324. Another possibility is to use critical illumination, whereby the illumination source 324 is moved further away from the condenser lens 330. This pattern then is imaged on the substrate 314 by the projection lens system 302.

The system furthermore can be provided with a number of measuring systems for increasing the optimum control of the process, e.g. an alignment system for aligning the electro-wetting mask 100 and the substrate 314 with respect to each other in the XY plane or a focus error detection system for determining a deviation between the focal or image plane of the projection lens system and the surface of the photoresist layer 316 on the substrate 314. These systems are parts of servosystems which comprise electronic signal-processing and control circuits and drivers, or actuators, with which the position and the orientation of the substrate 314 and the focusing can be corrected with reference to the signals supplied by the measuring systems.

In a fourth embodiment, a maskless optical lithographic system with a reflection configuration 400 is described for use with the reflection electro-wetting lithographic mask 200 of embodiment 2. A schematic representation of the system is shown in FIG. 6. Most components of the present invention are similar to the components in the above described embodiment. The characteristics and properties of these similar components as described in the above embodiment can be applied to the current embodiment. The system comprises an illumination source 324, a beam splitter 402, a reflection electro-wetting mask 200 with corresponding means 306 for controlling and driving the electro-wetting mask 200. The beam splitter 402 typically is made of quartz, CaF₂ or other typical lens materials. Similar as in the previous embodiment, the means for controlling and driving the electro-wetting mask 200 comprises means for inputting or receiving a digital pattern and means for either active matrix or passive matrix driving of the electro-wetting mask 200. The system furthermore comprises an optical system 404 including lenses 406 and an aperture 408. Furthermore, a substrate 314 can be fixed on a substrate table 310 comprising a substrate holder. The stage can be controlled with ultra precision using a laser interferometer 410.

In a fifth embodiment, another maskless optical lithographic system with a reflection configuration is described. This type of configuration typically is used with extreme ultraviolet illumination sources. The reflection configuration 500 comprises the same components as the reflection system described in the previous embodiments, but the conventional lenses are replaced by a mirror projection system 502. Different embodiments of mirror projection systems are known which may comprise three to six mirrors. The quality of the image enhances with increasing number of mirrors. An exemplary reflection configuration using a mirror projection system with six mirrors is shown in FIG. 7. The system comprises a reflection electro-wetting mask 200, a mask holder 304, a driving an controlling means 306 for the electro-wetting mask 200 and a substrate table 310 supporting a substrate holder 312 for accommodating a substrate 314. Furthermore, the system comprises an illumination source 324, which can be any of the other sources mentioned in the previous embodiments. Replacing the lens system by a mirror projection system is applicable for all illumination sources. It is furthermore especially useful if the wavelength of the illumination source used is low, e.g. if the 157 nm line of a krypton-fluoride excimer laser is used, as it allows to avoid the need for expensive deep UV lenses.

The illumination source 324 may be positioned close to the substrate table 310 and the imaging section of the projection system, so that the projection beam can enter the projection column closely along these elements. The reflection electro-wetting mask 200 to be imaged is arranged in a mask holder 304 which forms part of a mask table 504 by means of which the reflection electro-wetting mask 200 can be moved in the scanning direction and possibly in a direction perpendicular to the scanning direction, such that all areas of the mask pattern can be arranged under the illumination spot formed by the illumination source 324. The mask holder 304 and mask table are shown only diagrammatically and may be implemented in various ways. The substrate 314 is arranged on a substrate holder 312 which is supported by a substrate table 310. The substrate table 310 may move the substrate 314 in the scanning direction, the X direction, but also in the Y direction perpendicular thereto. In this embodiment, the reflection electro-wetting mask 200 and the substrate 314 move in the same direction during scanning.

The illumination beam reflected by the reflective electro-wetting mask 200 is incident on a first mirror 506 which is concave. This mirror 506 reflects the illumination beam as a converging beam to a second mirror 508 which is slightly concave. The mirror 508 reflects the illumination beam as a more strongly converging beam to a third mirror 510. This mirror 510 is convex and reflects the illumination beam as a slightly diverging beam to the fourth mirror 512. This mirror 512 is concave and reflects the illumination beam as a converging beam to the fifth mirror 514 which is convex and reflects the illumination beam as a diverging beam to the sixth mirror 516. This mirror 516 is concave and focuses the illumination beam on the photoresist layer provided on the substrate 314. The mirrors 506, 508, 510 and 512 jointly form an intermediate image of the mask and the mirrors 514 and 516 produce the desired telecentric image of this intermediate image on the photoresist layer. Also the mirror projection system 502 described above and other projection systems may have different aberrations which can be measured and for which can be corrected.

In a sixth embodiment, a maskless optical lithographic system using an electro-wetting mask is described for performing maskless optical lithography in a contact printing mode. In this embodiment, the maskless optical lithography is performed by bringing the electro-wetting mask 100 in contact with the photoresist layer. The lithographic setup thus uses the transmission electro-wetting mask 100. The mask pattern covers the whole part of the substrate that is to be patterned. The corresponding magnification is +1×. This technique allows performing optical lithography with high resolution. Nevertheless, due to the contact between the resist layer and the electro-wetting mask, the electro-wetting mask is subject of relative high wear and tear. Furthermore, due to the contact, the electro-wetting masks need to be cleaned regularly as fragments of the photoresist can stick to the mask during processing. To avoid this, a distance between the mask and the surface of the resist layer between 1 μm and 10 μm may be provided.

In a seventh embodiment, a maskless optical lithographic system using an electro-wetting mask is described for performing maskless optical lithography in a +1× printing mode. This embodiment has the same configuration as a transmission or reflection optical maskless lithography setup described in embodiments three and four. Furthermore, the same electro-wetting mask as in the previous embodiment can be used, i.e. a mask corresponding with a magnification of +1×, but this embodiment has the advantage of avoiding the wear and tear on the mask, while still a rather simple and elegant projection lens system can be used.

The electro-wetting lithographic masks as described in the previous embodiments have pixel sizes that are substantially smaller compared to e.g. lithographic masks based on spatial light modulation. Pixel sizes with a typical dimension below 1 micron are possible. Due to the smaller pixel size, the demagnification needed for electro-wetting pixels will be significantly smaller than the demagnification needed for spatial light modulation pixels. Furthermore the number of pixels can be significantly larger and is only limited by the maximum demagnification and the size of the active plate. Furthermore, the switching time scales down with dimensions. Another advantage is the low driving voltage of the pixels in the electro-wetting mask.

The present invention also relates to a method 600 for performing a lithographic processing step using a wafer scanner system with an electro-wetting mask, as shown in FIG. 8.

In a first step 602, a digital pattern is provided which is to be imaged on the substrate. This typically consists of a number of identical images corresponding with the number of identical IC's that will be made on the substrate. Although it is in principle possible to produce different non-identical IC's on a substrate, the differences between these IC's are restricted as the thicknesses of the coatings that need to be processed using lithography are typically the same over the whole substrate, i.e. wafer. The digital pattern provided can be constructed using conventional drawing and imaging programs. Depending on the optics of the optical lithographic system, the digital pattern may be used directly or may be first inverted.

In a following step 604, the substrate is provided with a coating and fixed on the alignment stage. The logical order of coating and fixing on the alignment stage can also be reversed, i.e. the coating can also be applied once the substrate is already fixed on the alignment stage. Furthermore, the actions of the current step 604, may be performed before step 602.

In step 606 a selection of the digital pattern is made by the controlling system. This step is typically for wafer scanners and wafer steppers whereby the mask does not cover the whole substrate at once. This is practically always the case in todays lithographic processing, as high resolution images are often required. If it concerns a first selection at the beginning of a lithographic process, selection of an area of the digital pattern is performed typically by selecting an area at the side of the digital pattern to be reproduced. If it concerns a further step, the selection of the digital pattern will be made in agreement with the status of the processing, i.e. depending on which parts of the wafer that already are processed. The coordinates of the area that is selected are transferred to the substrate stage.

In step 608 the selected portion of the digital pattern will be used to set the electro-wetting mask accordingly. This setting of the electro-wetting mask may be either performed by actively or passively matrix driving of the electro-wetting mask.

In step 610, alignment of the substrate is performed, based on the coordinates of the selected pattern area provided by the control system of the electro-wetting mask. Additionally, alignment markers may be used to improve the alignment. These alignment markers may be holes in the electro-wetting mask illuminated by the radiation source. Nevertheless, at this moment, the substrate is still blocked from the radiation source, e.g. by providing a shutter near the substrate.

In step 612, after the alignment has been finished, an illumination step is performed by opening and closing of a shutter that is blocking the illumination source from the substrate. If the radiation source is a pulsed radiation source, the illumination step also may be achieved by performing one or more illumination pulses, i.e. without the need of using a shutter. During this illumination step an area of the resist coating is illuminated with a pattern defined by the electro-wetting mask.

In decision step 614, it is determined whether another area of the substrate needs to be imaged. If so, method 600 proceeds to step 606, if not method 600 ends.

It can be of importance that the alignment during the lithographic processing is perfect, in order to assure that the combination of the patterning of the different selected regions corresponds with the patterning that is to be obtained in the whole substrate. Additional techniques can be provided to reduce the effects of stitching errors that have been made. For example, the areas could be selected so that there is an overlap with adjacent areas. The attenuation of the source light in these overlapping regions may be adjusted during setting of the electro-wetting mask, e.g. by attenuation of the voltage applied to the electro-wetting mask pixels in these overlapping regions. In this way a normal intensity can be obtained if stitching is performed perfectly, while the error will be less dramatic if the alignment is not perfect.

The invention further also relates to a lithographic mask 700 combining both a fixed mask 702, i.e. like the masks used in conventional non-maskless lithography, and a programmable electro-wetting mask 704. An example of such a combined mask is shown in FIG. 9. In this embodiment the lithographic mask 700 thus is spatially divided in regions having a conventional mask 702 and regions having a programmable electro-wetting mask 704. The conventional mask 702 typically may be a chrome-on quartz glass, having a chromium coating on the quartz mask in regions where there should be no transparency and having only quartz in the regions where transparency of the illumination radiation is necessary or it may be a phase shift mask or attenuated phase shift mask, which allows improved resolution, due to interference effects. Regions wherein the patterns to be used during lithographic processing do not change, are covered by these conventional masks 702, whereas regions wherein the pattern during the subsequent steps in the lithographic processing changes are covered by programmable masks 704. As the number of pixels to be driven is reduced in this way, this allows to change the mask pattern faster, which is advantageous for the overall processing speed.

The present invention also relates to a method for providing a unique label in each substrate or in each IC that is processed. Such a unique label can be used e.g. for identification purposes. It also allows improved quality control and more systematic detection of e.g. errors or contamination sources. The label can be applied in a region of the IC where no components or connections are present, by providing the unique identification label in the digital pattern to be applied. It can be provided during only one of the lithographic processing steps or during more of the lithographic processing steps. The label could also be provided in a separate step, which is solely performed for labelling the IC, i.e. not using a processing step in the production of the IC. The method can be performed using any maskless lithographic process. This process makes use of a programmable mask, which may be an electro-wetting mask, but also a lithographic mask based on a digital mirror device (DMD) or a liquid crystal light valves (LCLV). The electro-wetting mask may be either a transmission or reflection mask according to the embodiments described above. The masks based on DMD or LCLV are known by a person skilled in the art, e.g. from U.S. Pat. No. 6,312,134 (Anvik Corporation). Labelling a substrate is performed by first providing one or more unique indicia, such as one or more numbers, one or more alphanumeric or one or more alphabetic characters in the digital pattern, used for patterning the substrate and illuminating the substrate through the programmable mask. The method also may be applied to uniquely identify different dies on a substrate, i.e. to uniquely identify ICs. Several unique identification labels then are provided in the digital pattern for the whole substrate, such that each IC has its unique identification label. This label may be a number and it also may include the date and time of processing. If the method is applied to a plurality of substrates, e.g. to a batch of wafers, the method may be used for uniquely identifying every IC on every substrate. The sequence of indicia or numbering then does not restart if a new substrate is patterned.

In a further embodiment of the invention, another method of performing optical maskless lithography can be provided. In this method, during illumination with a narrow illumination beam, the illuminated part of the electro-wetting mask is continuously refreshed. In this mode the applied pattern is continuously changed. The subsequent patterns applied to the electro-wetting mask then correspond with the patterns obtained during scanning of the digital image pattern for the whole substrate. At the same time, the substrate is shifted by the translation stage supporting the substrate with a predetermined speed such that the illumination pattern applied to the photoresist corresponds with the digital image pattern for the whole substrate. Applying this method is possible as the refresh rate of the electro-wetting mask can be significantly high. In this way, the error made by moving the substrate during illumination is negligible as the refresh rate is significantly high compared to the speed with which the substrate is moved.

In a further embodiment of the invention, a further method of performing optical maskless lithography is provided. In this method, only a part of the sub-area of the electro-wetting mask is used for patterning the substrate. During illumination, i.e. in between pulses if a pulsed illumination source is used or during a temporary blocking of the illumination beam if a continuous working illumination source is used, the sub-area of the electro-wetting mask used is changed to a new sub-area of the electro-wetting mask, so that during a subsequent pulse or illumination period, the same pattern can be provided on the same area of the wafer using another part of the electro-wetting mask. By changing the area of the electro-wetting mask used to provide a single pattern, errors, e.g. caused by pixels that can not be driven anymore, present in a certain sub-area of the mask have only a limited influence on the final pattern obtained, as the corresponding sub-area is only used during a fraction of the total illumination time of that pattern. Due to the possibility to have a high refresh rate, the above mentioned method can be used with a relative high throughput of substrates.

It is to be understood that although preferred embodiments, specific constructions and configurations, as well as materials, have been discussed herein for devices according to the present invention, various changes or modifications in form and detail may be made without departing from the scope and spirit of this invention. For example, whereas specific embodiments of this invention are described with respect to a wafer stepper respectively a wafer scanner, it is also possible to provide these embodiments in a wafer scanner respectively wafer stepper mode. Whereas in a wafer stepper different predetermined areas are patterned at once in different subsequent steps, in wafer scanners, the mask and the wafer are scanned simultaneously through a lens field e.g. shaped like a narrow arc.

A maskless lithography system is described having a programmable mask to allow performing several lithographic steps using the same mask. In every lithographic step, the corresponding pattern is obtained by providing a digital pattern to the programmable mask. The programmable mask includes an array of pixels which are based on the electro-wetting principle. According to this principle, every pixel has a transparent reservoir containing a first, non-polar, non-transparent fluid and a second, polar, transparent fluid which are immiscible. Applying a field to the reservoir allows to displace the fluids with respect to each other. This allows to make the pixel either transparent or non-transparent. This lithographic programmable mask allows high resolution and fast setting and refreshing. A corresponding method for performing maskless optical lithography also is described.

1. A programmable lithographic mask (100) for use in an optical lithographic setup (300) using a lithographic illumination source (324), said programmable mask (100) comprising a number of pixels, each pixel comprising a first, non-polar fluid (110) that is not transparent for the lithographic illumination source (324) and a second, polar fluid (112) that is transparent for the lithographic illumination source (324), said fluids being immiscible; said programmable lithographic mask (100) furthermore comprising means (306) for driving every pixel to thereby displace said first and second fluids with respect to each other on a pixel-by-pixel basis.

2. A programmable lithographic mask (100) according to claim 1, furthermore comprising a reservoir having walls transparent for the radiation from the lithographic illumination source (324) and containing said first, non-polar fluid (110) and said second, polar fluid (112).

3. A programmable lithographic mask (100) according to claim 2, wherein one of said walls is a lyophobic wall, repelling said second, polar fluid (112).

4. A programmable lithographic mask (100) according to claim 1, said pixels furthermore each comprising an electrode (102) for applying an electric field to said fluids.

5. A programmable lithographic mask (100) according to claim 4, wherein the electrodes (102) are transparent for the radiation from the lithographic illumination source.

6. A programmable lithographic mask (100) according to claim 4 comprising a reflective coating.

7. A programmable lithographic mask (100) according to claim 1, wherein said means for driving (306) every pixel is means for active matrix driving.

8. A programmable lithographic mask (100) according to claim 1, wherein said means for driving (306) every pixel is means for passive matrix driving.

9. A programmable lithographic mask (100) according to claim 1, wherein said first, non-polar fluid (110) is an oil and said second, polar fluid (112) is an aqueous solution or water.

10. A programmable lithographic mask (100) according to claim 1, furthermore comprising means for providing a fixed, non-programmable pattern in a number of areas of said programmable lithographic mask.

11. A system for maskless optical lithography (300), said system comprising
an illumination source (324),
a programmable lithographic mask (100) according to claim 1, and
controlling and driving means (306) for setting said programmable lithographic mask (100) according to a lithographic pattern and for driving said pixels of said programmable lithographic mask (100) in accordance with the pattern.

12. A system for maskless optical lithography (300) according to claim 11, furthermore comprising a first optical means (326) for focussing an illumination beam of said illumination source (324).

13. A system for maskless optical lithography (300) according to claim 12 wherein said focussing an illumination beam is performed based on the Köhler principle.

14. A system for maskless optical lithography (300) according to claim 11, furthermore comprising a second optical means (302) for guiding and focussing said illumination beam, modulated according to said lithographic pattern of the programmable lithographic mask (100).

15. A system for maskless optical lithography (300) according to claim 11, further comprising means for aligning (310) said substrate (314) relative to said programmable lithographic mask (100).

16. A system for maskless optical lithography (300) according to claim 11, further comprising a blocking means for blocking said illumination beam during alignment and during setting of the programmable lithographic mask (100).

17. A system for maskless optical lithography (300) according to claim 11 wherein said first and second optical means are based on mirrors, beamsplitters and/or lenses.

18. A system for maskless optical lithography (300) according to claims 11, wherein said pixels of said electro-wetting mask (100) furthermore comprise means to reflect the illumination beam that has passed the first and/or the second fluid.

19. A method for performing an optical lithographic step on a substrate, comprising the steps of
providing a digital pattern to a controlling and driving means (306) of an electro-wetting mask (100), and
using the digital pattern to modulate a light pattern by means of the electro-wetting mask (100), and
illuminating the substrate (314) through the electro-wetting mask (100).

20. A method according to claim 19, further comprising mounting the substrate (314) on an substrate stage (310) and aligning the substrate relative to the electro-wetting mask (100).

21. A method according to claim 19, further comprising coating the substrate (314) with a photosensitive material (316) before illumination of the substrate (314).

22. A method according to claim 20, wherein during said illuminating of the substrate (314), the electro-wetting mask (100) and the substrate (314) are moved in the same direction or the electro-wetting mask (100) and the substrate (314) are moved in opposite directions.

23. A method according to claim 20, wherein said illuminating is performed by scanning the electro-wetting mask (100) with a narrow beam and at the same time shifting the substrate (314) accordingly, to illuminate the substrate (314) with the corresponding lithographic pattern.

24. A method for labelling a substrate (314) in an optical lithographic step, comprising the steps of
providing at least one unique identification label in a digital pattern in order to provide every substrate (314) with that unique identification label.
providing said digital pattern to a controlling and driving means of an electro-wetting mask (100), and
using the digital pattern to modulate a light pattern by means of the electro-wetting mask (100), and
illuminating the substrate through the electro-wetting mask (100).

25. A method according to claim 24, furthermore comprising, providing unique identification labels in the digital pattern in order to provide every die on a substrate (314) with a unique identification label.

26. A method according to claim 25 wherein said unique identification labels in the digital pattern are refreshed during optical lithography of a plurality of substrates (314), as to provide a unique identification label for every die of said plurality of substrates (314).

27. A method of making a device, said method comprising
providing a photoresist layer (316) on a layer which is to be patterned
illuminating the photoresist layer (316) with a corresponding pattern obtained by modulating an illumination source with an electro-wetting mask (100)
developing said photoresist layer (316)
processing the substrate (314) to obtain the patterned layer.
